(19) United States
(12) Patent Application Publication
(10) Pub. No.: US 2006/0200714 A1
(43) Pub. Date: Sep. 7, 2006

(54) Test equipment for semiconductor

(75) Inventors: Satoru Kamano, Katano-shi (JP); Tomohiko Kanemitsu, Toyonaka-shi (JP)

Correspondence Address: MCDERMOTT WILL & EMERY LLP, 600 13TH STREET, N.W., WASHINGTON, DC, 20005-3096, US

(73) Assignee: Matsushita Electric Industrial Co., Ltd.

(21) Appl. No.: 11/363,948

(22) Filed: Mar. 1, 2006

(30) Foreign Application Priority Data
Mar. 1, 2005 (JP) 2005-056332

(51) Int. Cl. G11C 29/00

(52) U.S. Cl. 714/718

(57) ABSTRACT

A test equipment for semiconductor according to the present invention comprises a equipment main body and a memory cell provided in an outside of the equipment main body, wherein the equipment main body comprises a configurable device capable of making a hardware construction in a programmable manner and an interface for connecting the configurable device to the outside of the equipment main body in order to configure the configurable device, and the memory cell, in which a regulation program for the hardware construction for regulating the hardware construction of the configurable device is written, is connected in freely attached or removed way to the configurable device via the interface.

### BACKGROUND OF THE INVENTION

1. Field of the Invention

The present invention relates to a test equipment for semiconductor comprising a configurable device capable of constructing a hardware construction in a programmable manner such as FPGA (Field Programmable Gate Array).

2. Description of the Related Art

In recent years, the development of a system LSI comprising a plurality of circuits has been rapidly advancing, and various equipments and methods for testing the system LSI, which respectively meet different requirements such as testing costs and test details, have been proposed. Focusing on the subject of costs, a general-purpose tester comprising a circuit and a exclusive device for a signal input/output unit and a control unit is expensive. In order to reduce the testing costs, a test equipment for semiconductor at a low price has been developed to do input/output and control of a signal using a configurable device (FPGA).

FIG. 9 is a schematic diagram illustrating a construction of a low-priced test equipment using the FPGA according to a conventional method. A main body A′ of the test equipment for semiconductor according to the method comprises a test head 11, a FPGA 12, a measurement unit 13, a memory 14, a power-supply unit/clock generating unit 15, and a memory cell 21. A program is written into the memory cell 21 to regulate a hardware structure by configuration of the FPGA.

The equipment main body A′ is operated together with a load board C interfacing with a device B as a test object and a PC/EWS (Engineering Work Station) 100 to control the main body A′ from the outside. The PC/EWS means a personal computer or an engineering work station. A role of the respective components is described below.

The test head 11 comprises a tester channel comprising a connector, a pogo pin, a cable and the like, and exchanges digital and analog signals between the FPGA 12 and the measurement unit 13, and the load board C. The measurement unit 13 has a function, for example, to read a voltage value outputted from the device B to be tested via the load board C, or convert a read analog value into a digital value, and the like. The power-supply unit/clock generating unit 15 supplies a power and a clock necessary for the test to the FPGA 12 and the load board C. The memory 14 stores therein a data for inputting/outputting a logic pattern used in testing the device B as the test object (information such as output value and an expected value) and a data outputted from the device B to be tested. These data are stored in the memory 14 via the load board C. The FPGA 12 carries out input/output and calculation of the data and control of the memory 14, and the like. The FPGA 12, for example, outputs the data stored in the memory 14, compares the data inputted via the load board C to the data stored in the memory 14, and takes in the data inputted via the load board C and executes a calculation. The FPGA 12 is operated based on a test program from the PC/EWS 100. A program is written into the memory cell 21 to regulate a hardware structure for configuration of the FPGA. Thus, the FPGA 12 is mainly in charge of a logic testing function of the device B to be tested in the equipment main body A′.

Next, an operation of the test equipment for semiconductor according to the conventional method is described. When the electric power of the equipment main body A′ is turned on, the information of the memory cell is configured to the FPGA 12. Thereby, the hardware construction of the FPGA 12 and then a hardware construction for the logic testing function of the equipment main body A′ are regulated. The regulated hardware constructions are fixed irrespective of the device B to be tested.

Next, after the load board C is mounted on the test head 11, and the device B to be tested is mounted on the load board C, the test program for the device B to be tested is executed in the PC/EWS 100. The FPGA 12 is operated based on the test program to execute input/output of the logic pattern to carry out the test. When the test is completed, the FPGA 12 output a result of the test to the PC/EWS 100.

The system LSI with higher performance and a great variety has been commercialized one after another in recent years. Accordingly, a specification for testing requested to the test equipment for semiconductor is largely different with respect to each of the system LSI. For example, there are difference in a frequency and an output voltage in case of inputting/outputting the logic pattern, and a range of corresponding channels and a range of corresponding frequencies when a frequency counting function and a digital capture function are used, and the like.

In the foregoing conventional construction, the specific program written in the memory cell 21 is configured to the FPGA 12 so that the hardware construction for the logic testing function of the test equipment for semiconductor is regulated. However, the FPGA 12, whose resource is limited, is incapable of providing an optimum hardware construction of the test equipment for semiconductor for each device to be tested. A hardware construction suitable for a device to be tested is not necessarily also the most suitable for another device to be tested.

### SUMMARY OF THE INVENTION

Therefore, a main object of the present invention is to heighten general-purpose property of a low-priced test equipment for semiconductor in which a configurable device, such as FPGA, is used by constructing a hardware construction that is optimum for each of a plurality of devices to be tested.

In order to achieve the foregoing object, a test equipment for semiconductor according to the present invention comprises a equipment main body and a memory cell provided in an outside of the equipment main body. The equipment main body comprises a configurable device capable of constructing a hardware construction in a programmable manner and an interface to connect the configurable device and the outside of the equipment main body in order to configure the configurable device. The memory cell, in which regulation program to a hardware construction for regulating the hardware construction of the configurable device is written, is connected to the equipment main body via the interface to be freely attached or removed.

According to the foregoing construction, the memory cell, in which the program for regulating the hardware construction of the configurable device is written, is provided separately from the main body of the test equipment for semiconductor, and thereby a regulation program for the hardware construction can be flexibly changed depending on the device to be tested, which is configured to the configurable device via the interface. Therefore, it is possible to construct the hardware construction optimum for each of a plurality of devices to be tested and heighten general-purpose property of the test equipment for semiconductor.

In the foregoing construction, it is preferable that the configurable device executes the test program in which an operation of the test equipment for semiconductor is regulated after the configurable device is configured based on the regulation program for the hardware construction read out from the memory cell.

According to the foregoing construction, it is possible to control the operation of the test equipment for semiconductor necessary for performing the following test by a personal computer (including an engineering work station) The test recited here is to test a logic circuit part and an analog circuit part in the device to be tested after the hardware construction suitable for testing the device is configured to the configurable device.

In the foregoing construction, the interface is preferable to have a connector or a pogo pin to which the configurable device is connected.

According to the foregoing construction, configuration can be done to the configurable device built in the test equipment for semiconductor via the connector or pogo pin from the personal computer connected to a configuration cable or the like, or a load board on which the memory cell is mounted.

Referring to a position of the memory cell placed in the outside of the equipment main body in the foregoing construction, there are the examples that the memory cell is mounted on the load board which connects the device to be tested and the equipment main body or is installed in the personal computer (including the engineering work station).

According to the foregoing construction, the configuration can be easily carried out about the program suitable for the device to be tested from the load board, BOST (external auxiliary circuit for performing the test), or personal computer or the like. In the case where it is necessary to change the hardware construction of the configurable device depending on a type of the device as the test object, the memory cell is mounted on the load board or BOST prepared for the device to be tested so that it becomes unnecessary to change the memory cell every time when the respective devices as the test object are tested. As a result, the test can be carried out more efficiently by reducing a number of times for changing the memory cell.

In the foregoing construction, there is an example that a device recognizing a memory cell is further added to recognize a connection state of the memory cell and output a result of the recognition. In the embodiment, it is preferable that another memory cell is further provided wherein another regulation program for hardware construction for regulating another hardware construction of the configurable device is written. In this example, it is thought that one is the another memory cell built in the equipment main body or installed in the personal computer connected to the test equipment for semiconductor in order to execute the test program in which the operation of the test equipment for semiconductor is regulated. In the foregoing embodiments, the configurable device reads out the regulation program for the hardware construction of the memory cell and is configured based on the read program when the circuit recognizing the memory cell recognizes the connection of the memory cell, while the configurable device reads out the another regulation program for the hardware construction of the another memory cell and is configured based on the another program when the circuit recognizing the memory cell in not aware of the connection of the memory cell.

According to the foregoing construction, the circuit recognizing the memory cell can judge whether or not the memory cell is mounted on the load board immediately after the load board is mounted on the equipment main body, and output a warning signal or have the configurable device configured using the another memory cell built in the equipment main body when the memory cell is not mounted. In other words, general-purpose property are given by arrangement of the plurality of memory cells can diversify the test, and flexible correspondence can be taken in accordance with the arrangement location of the memory cell.

In the foregoing construction, there is another example that a board information on the load board is memorized in the memory cell, and the configurable device conducts the test in which the operation of the device for testing semiconductor is regulated based on the board information on the load board which is read out from the memory cell.

According to the foregoing construction, the board information, such as a propagation delay characteristic that is different every load board, can be made read into the configurable device, personal computer, engineering work station or the like in the same manner as the hardware construction. As a result, it is possible to eliminate a preliminary process such as calibration before the test program which was conventionally required.

Further, in the foregoing construction, there is an example that a self-diagnosis program for automatically diagnosing parts loaded in the equipment main body is written in the memory cell.

According to the foregoing construction, the self-diagnosis process can be automatically executed when the memory cell is connected so that a self-diagnosis process of the equipment main body, which was conventionally done separately from the test, becomes unnecessary, and reliability on the test can be raised because the diagnosis can be always conducted before the execution of the test program.

In the foregoing construction, there is another embodiment that a circuit selecting a memory cell may be further provided and a plurality of memory cells may be installed, wherein a circuit selecting a memory cell selects an arbitrary memory cell from the plurality of memory cells connected to the interface, and the test is performed based on the test program in which the operation of the test equipment for semiconductor is regulated after the configurable device is configured based on the regulation program for the hardware construction which is readout from the memory cell selected by the circuit selecting the memory cell.

According to the foregoing construction, the plurality of different memory cells are mounted on the load board, and the circuit selecting the memory cell switches the memory cell during the test so that the test can be performed under the optimum hardware construction of the configurable device every test of the device to be tested.

In the foregoing construction, it is thought as another example that a collate circuit for collating a discrimination signal from the device to be tested, personal computer or the like with a discrimination signal from the memory cell and a result of the collation is outputted.

According to the foregoing construction, when the program written in the memory cell is not suitable for the device to be tested, the collate circuit outputs the collation result prior to the test to thereby eliminate such a risk that the test may be performed based on the wrong hardware construction and test program. Practically speaking, the operation of the equipment main body can be halted, or the like, based on the collation result.

As thus far described, the present invention can heighten a general-purpose property of the low-priced test equipment for semiconductor in which the configurable device (FPGA) is used for the input/output and control of the signal.

The test equipment for semiconductor according to the present invention is effective as a test equipment for semiconductor comprising a configurable device capable of constructing hardware constructions in a programmable manner such as FPGA.

### BRIEF DESCRIPTION OF THE DRAWINGS

These and other objects as well as advantages of the invention will become clear by the following description of preferred embodiments of the invention. A number of benefits not recited in this specification will come to the attention of the skilled in the art upon the enforcement of the present invention.

FIG. 1 is a block diagram illustrating a schematic construction of a test equipment for semiconductor according to an embodiment 1 of the present invention.

FIG. 2 is a block diagram illustrating a schematic construction of a test equipment for semiconductor according to a modified embodiment of the embodiment 1.

FIG. 3 is a block diagram illustrating a schematic construction of a test equipment for semiconductor according to an embodiment 2 of the present invention.

FIG. 4 is a block diagram illustrating a schematic construction of a test equipment for semiconductor according to an embodiment 3 of the present invention.

FIG. 5 is a block diagram illustrating a schematic construction of a test equipment for semiconductor according to an embodiment 4 of the present invention.

FIG. 6 is a block diagram illustrating a schematic construction of a test equipment for semiconductor according to an embodiment 5 of the present invention.

FIG. 7 is a block diagram illustrating a schematic construction of a test equipment for semiconductor according to an embodiment 6 of the present invention.

FIG. 8 is a block diagram illustrating a schematic construction of a test equipment for semiconductor according to an embodiment 7 of the present invention.

FIG. 9 is a block diagram illustrating a schematic construction of a conventional test equipment for semiconductor.

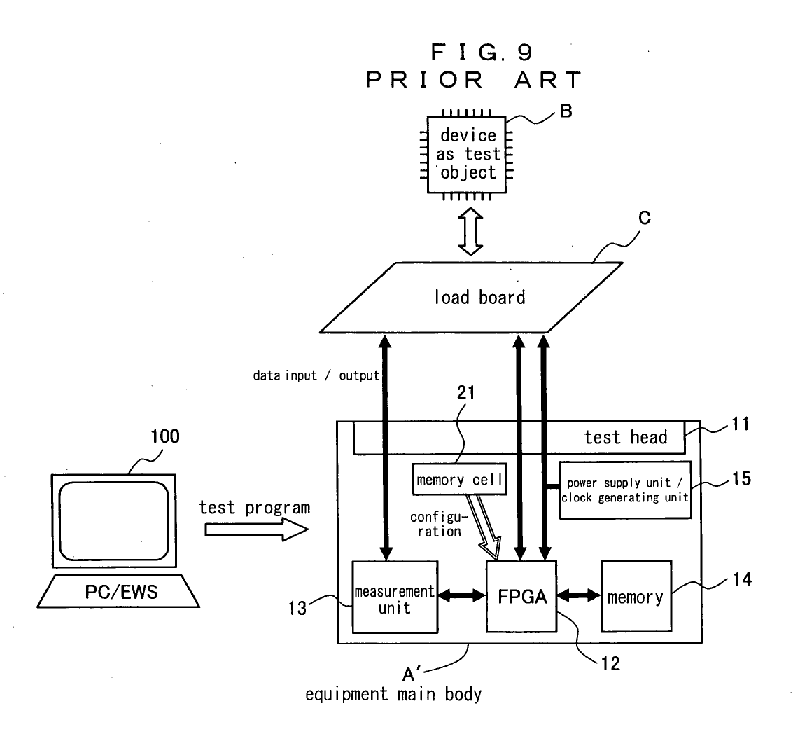

### DETAILED DESCRIPTION OF THE INVENTION

Hereinafter, preferred embodiments of a test equipment for semiconductor according to the present invention are described in detail referring to the drawings.

### Embodiment 1

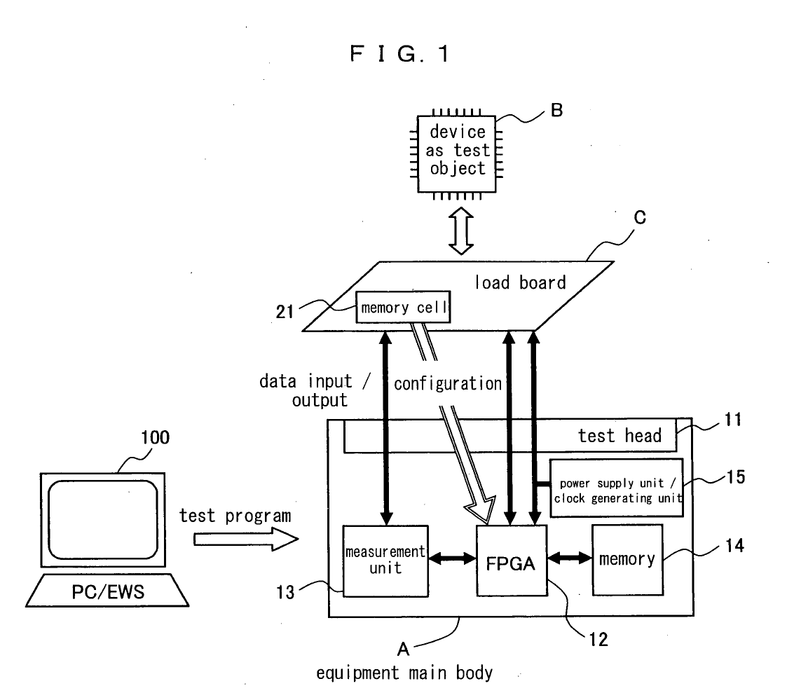

FIG. 1 is a block diagram illustrating a schematic construction of a test equipment for semiconductor according to an embodiment 1 of the present invention. In FIG. 1, A denotes a main body of the test equipment for semiconductor, B denotes a device as a test object, C denotes a load board on which the device B to be tested is mounted, 11 denotes a test head, 12 denotes FPGA as a configurable device, 13 denotes a measurement unit, 14 denotes a memory, 15 denotes a power-supply unit/clock generating unit, 21 denotes a memory cell in which a program for regulating a hardware construction of the FPGA 12 is written, and 100 denotes a PC/EWS. The “PC/EWS is a personal computer (including an engineering work station) connected to the test equipment for semiconductor and executing a test program in which an operation of the test equipment for semiconductor is regulated. The load board C is connected in a way to be freely attached or removed to the equipment main body A via the test head. In the description below, an information written in the memory cell 21 including the above program is simply referred to as information.

First, it is description is given about a role of the respective components. The test head 11 comprises an interface (tester channel) comprising a connecter, a pogo pin, a cable and the like. The test head 11 exchanges digital and analog signals between the load board C arranged outside of the equipment main body A, and the FPGA 12 and the measurement unit 13 provided inside the equipment. Functions of the measurement unit 13 are, for example, to read a voltage value outputted from the device B to be tested via the load board C, convert an analog value to a digital one, and the like. The power-supply unit/clock generating unit 15 supplies power and clock required for the test to the FPGA 12, the load board C and the like. The memory 14 stores therein a data for inputting/outputting a logic pattern necessary for testing the device B as the test object (information such as an output value and an expected value) and a data outputted from the device B via the load board C.

The information (including the regulation program for the hardware construction of the FPGA 12) is transmitted from the memory cell 21 to the FPGA 12. The FPGA 12 is configured based on the information to conduct an input/output of the data, calculation of the data, and control of the memory 14. The FPGA 12, for example, outputs the data stored in the memory 14 and compares the data inputted via the load board C to the data stored in the memory 14. The FPGA 12 further takes in the data inputted via the load board C and carries out calculation thereto. The FPGA 12 is operated based on the test program from the PC/EWS 100. The information for regulating the hardware construction of the FPGA 12 is written in the memory cell 21, and the hardware construction of the FPGA 12 is configured based on the information. The hardware construction regulated by the configuration can be flexibly changed in compliance with the device B as the test object. For example, when a logic test of the device B to be tested is performed based on the pattern stored in the memory 14, a bit number and a number of lines in the pattern input/output can be changed if necessary. Provided that a capacitance of the memory 14 is 512 megabytes and if one data is equivalent to 2 bits, it can be changed to 512 bits×4 mega bits lines or 256 bits×8 mega bits lines. Alternatively, the device B as the test object can be tested at an optimal construction with regard to an input/output frequency of the pattern, input/output voltage, channel range corresponding to data capture and the like. The input/output voltage, which is one of the conditions for the optimum construction, is limited to an input/output voltage under a construction wherein not only an I/O voltage value supplied to FPGA is made variable but also an I/O voltage is made variable about FPGA. Further, channel range corresponding to data capture means not a range where the data outputted from the device B to be testepd is compared to an expected value, but a range where the data value is stored in the memory.

Next, it is described about an example of the operation of the test equipment for semiconductor constructed as mentioned above. First, a power supply of the main body A of the test equipment for semiconductor is turned on. At the time, a power supply to the memory cell 21 via the load board C is in an off state. The load board C is mounted on the equipment main body A, it is controlled to turn on the power supply from the PC/EWS 100 to the memory cell 21 and start the configuration of the FPGA 12 at the same time. Thereby, the information of the memory cell 21 is transmitted to the FPGA 12, and the FPGA 12 is configured based on the transmitted information. As a result of the configuration, the hardware construction of the FPGA 12 and then a hardware construction of a logic testing function of the equipment main body A are regulated. The memory cell 21, which is provided outside of the equipment main body A, is capable of flexibly changing the information written therein. Therefore, the hardware construction for the logic testing function, which is optimum for the device B to be tested, can be configured.

Next, the device B as the test object is mounted on the load board C. Then, the test program for the device B as the test object is executed in the PC/EWS 100. The FPGA 12 is operated based on the test program, followed by the pattern input/output and the like to carry out the test. Then, the test is performed. When the test is completed, the FPGA 12 outputs a result of the test to the PC/EWS 100.

When a different device B as the test object is tested, a different memory cell 21, in which a hardware construction of a logic testing function optimum for the relevant device B as the test object is written, is used to carry out the test by configuring the FPGA 12 again.

According to the present embodiment, the hardware construction of the test equipment for semiconductor can be optimized in compliance with the device to be tested in order to give the test equipment for semiconductor with a low-price and higher general-purpose property. Therefore, it becomes unnecessary to prepare not only the various kinds of test equipments for semiconductors according to the different devices to be tested but also an expensive test equipment for semiconductor with a high general-purpose property. As a result, the cost of equipment can be reduced.

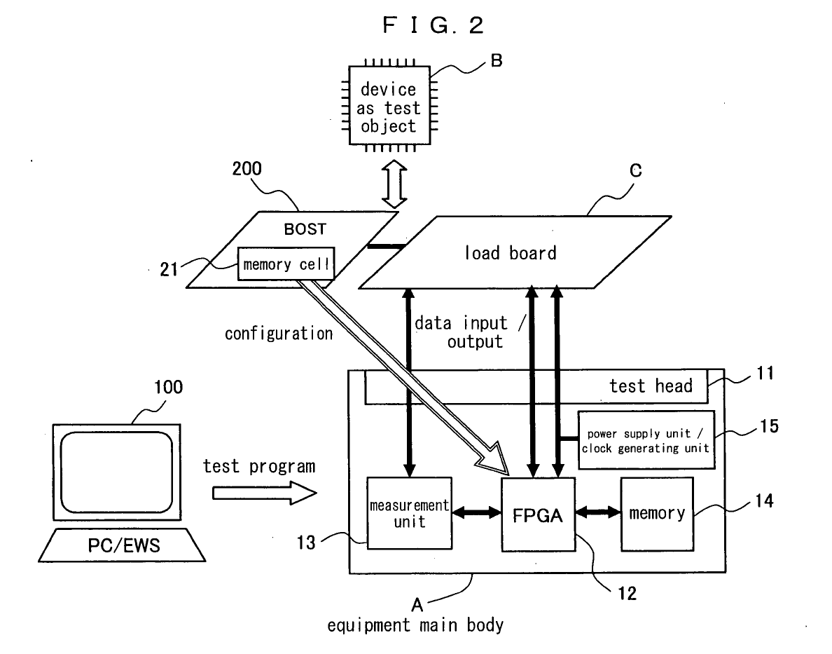

Though the memory cell 21 is mounted on the load board C in the present embodiment, it can be thought that the memory cell 21 can be mounted on a component other than the load board C, for example, a BOST (external auxiliary circuit for performing the test) 200 shown in FIG. 2. In this case, the memory cell 21 transmits the information to the FPGA 12 via a cable or a pogo pin so that the FPGA 12 is configured.

### Embodiment 2

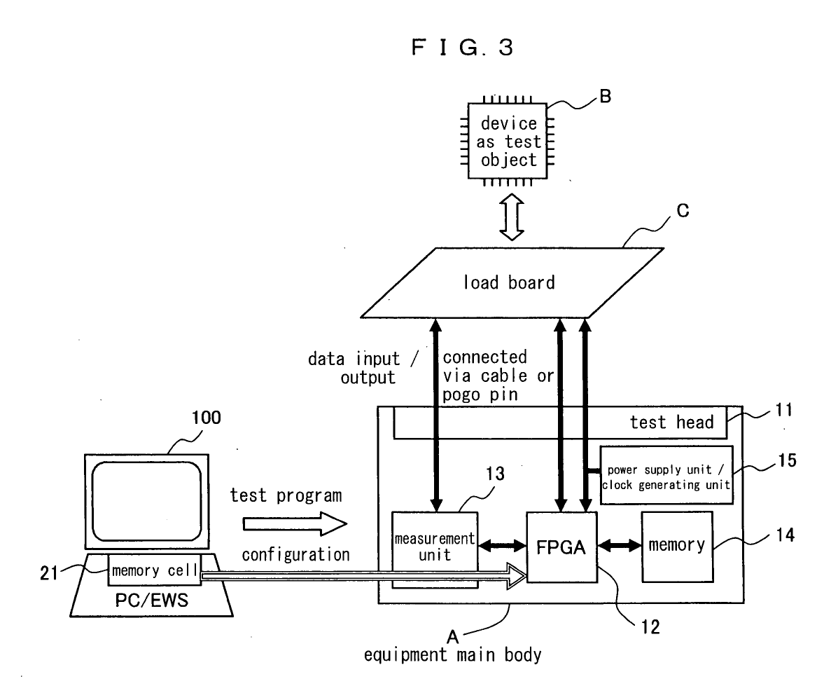

FIG. 3 is a block diagram illustrating a schematic construction of a test equipment for semiconductor according to an embodiment 2 of the present invention. The same marks as those shown in FIG. 1 according to the embodiment 1, which denote the same components, are not described in detail here. In the present embodiment, the memory cell 21, in which the program is memorized for regulating the hardware construction of the FPGA 12, is installed in the PC/EWS 100. The other construction is the same as described in the embodiment 1.

Next, it is described about an example of the operation of the test equipment for semiconductor constructed as mentioned above. After the load board C is mounted on the test head 11 of the equipment main body A, the information is transmitted from the memory cell 21 in the PC/EWS 100 to the FPGA 12 via the cable or the like. The FPGA 12 is configured based on the transmitted information, and the hardware construction for the logic testing function of the equipment main body A is thereby regulated. The operation thereafter is the same as described in the embodiment 1.

In the present embodiment, the program to regulate the hardware construction of the FPGA 12 is stored in the memory cell 21 in the PC/EWS 100, and a memory generally included in the PC/EWS 100 is used for the memory cell 21. Therefore, it becomes unnecessary to provide the memory cell for the exclusive use of the program, so it reduces the costs. It is to be noted, however, that the embodiment 1 is superior to the present embodiment in terms of security because the program can be easily referenced.

### Embodiment 3

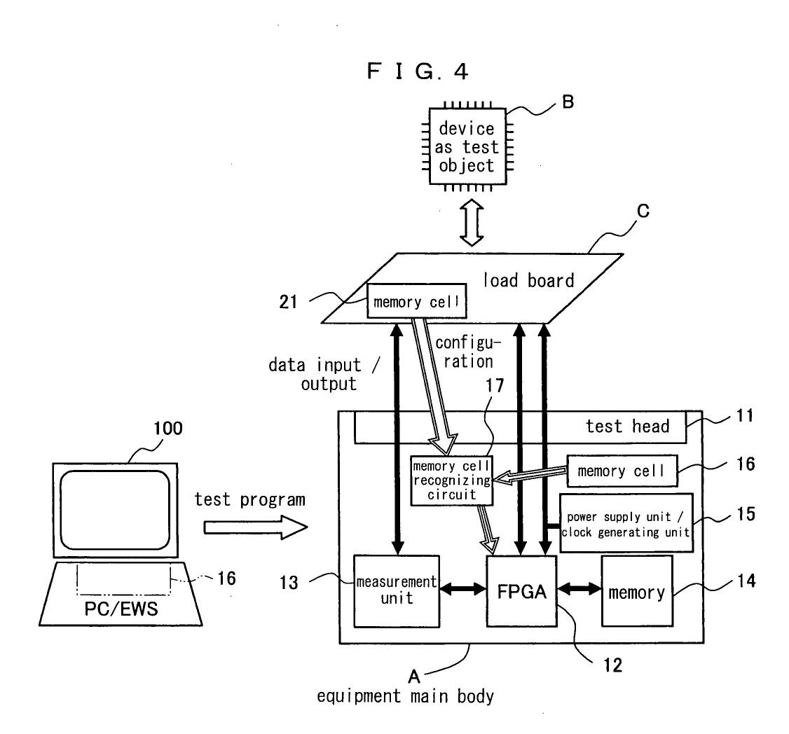

FIG. 4 is a block diagram illustrating a schematic construction of a test equipment for semiconductor according to an embodiment 3 of the present invention. The same marks as those shown in FIG. 1 according to the embodiment 1, which denote the same components, are not described in detail here. In the construction according to the present embodiment C, another memory cell 16 is loaded inside the main body A of the test equipment for semiconductor.

Further, a circuit recognizing memory cell 17 is loaded for recognizing whether or not the load board C provided with the memory cell 21 is connected to the equipment main body A and outputting a signal based on a result of the recognition. The other construction is the same as described in the embodiment 1.

Next, description is given about an example of the operation of the test equipment for semiconductor constructed as mentioned above. When the load board C is mounted on the test head 11 of the equipment main body A, the circuit recognizing memory cell 17 judges whether or not the memory cell 21 is mounted on the load board C. When the circuit recognizing memory cell 17 judges that the memory cell 21 is mounted on the load board C, the FPGA 12 is configured based on the information of the memory cell 21. On the contrary, when the circuit recognizing memory cell 17 judges that the memory cell 21 is not mounted on the load board C, the FPGA 12 is configured based on the information of the another memory 16 built in the equipment main body A. According to the FPGA 12 thus configured, the hardware construction for the logic testing function of the equipment main body A is regulated. The operation thereafter is the same as described in the embodiment 1.

In the present embodiment, the another memory cell 16 and the circuit recognizing memory cell 17 are built in the equipment main body A, it becomes unnecessary to mount the memory cell 21 on the load board C when the test is performed based on the hardware construction for the logic testing function regulated by the another built-in memory cell 16.

In the foregoing description of the present embodiment, another memory cell 16 is built in the equipment main body A. However, it can be thought that the memory cell 16 can be installed not in the equipment main body A but in the PC/EWS 100 (the memory of the PC/EWS 100 is used as the another memory cell 16) as shown in a dotted line in FIG. 4. In this case, the FPGA 12 is configured based on the information of the memory of the PC/EWS 100 (another memory cell 16) when the memory cell 21 is not mounted on the load board C.

### Embodiment 4

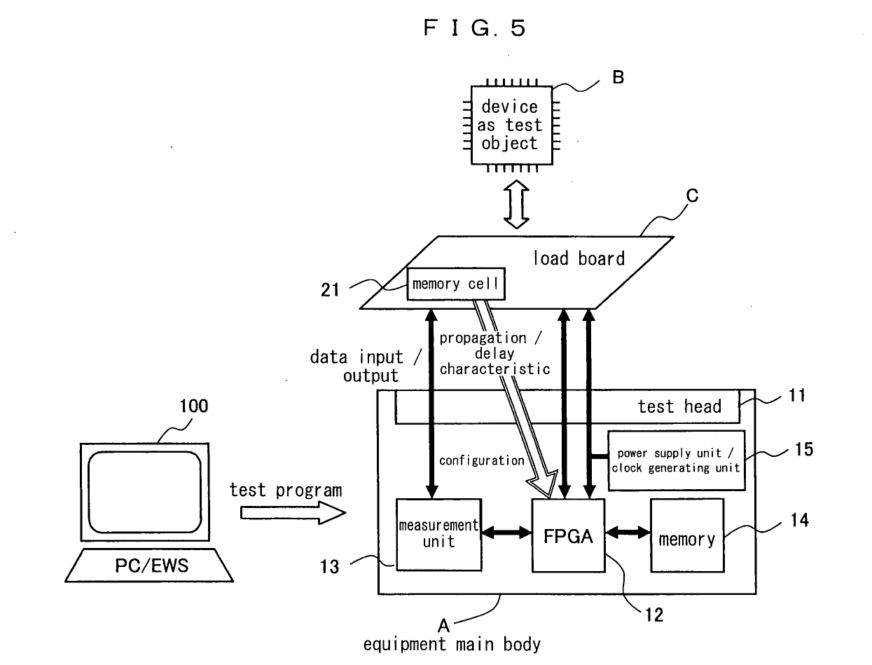

FIG. 5 is a block diagram illustrating a schematic construction of a test equipment for semiconductor according to an embodiment 4 of the present invention. The same marks as those shown in FIG. 1 according to the embodiment 1, which denote the same components, are not described in detail here. In the construction according to the present embodiment, the memory cell 21 stores therein aboard characteristic information, such as a propagation/delay characteristic of the load board C, other than the hardware construction for the logic testing function. The other construction is the same as described in the embodiment 1.

Next, description is given about an example of the operation of the test equipment for semiconductor constructed as mentioned above. After the load board C is mounted on the test head 11 of the equipment main body A, the FPGA 12 is configured to by means of the memory cell 21 via the cable or the like. The hardware construction for the logic testing function of the equipment main body A is regulated by the configuration. At the same time as the configuration or at a different timing, the board characteristic information of the load board C is written in the FPGA 12. The operation thereafter is the same as described in the embodiment 1. The device B as the test object is tested in reference to the board characteristic information written in the FPGA 12. For example, a timing of the signal outputted from the FPGA 12 is adjusted based on the delay information of the load board C and the device B as the test object is tested.

In the present embodiment, the memory 21 has the board characteristic information such as the propagation/delay characteristic of the load board C. Thereby, the test can be performed in such a manner that a characteristic variation between the boards is eliminated without a preliminarily checking the board characteristic of the load board C before the test started as done conventionally.

### Embodiment 5

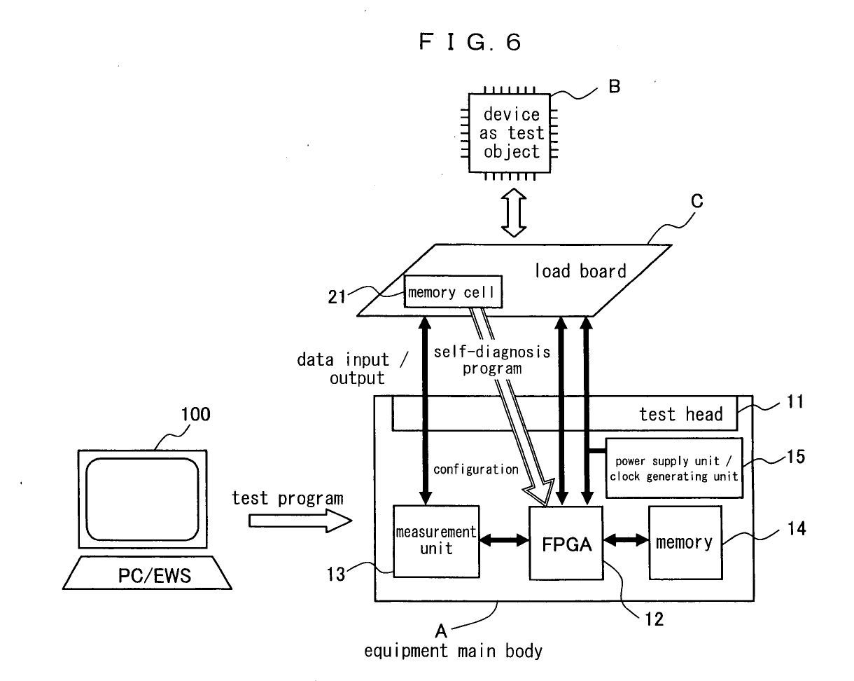

FIG. 6 is a block diagram illustrating a schematic construction of a test equipment for semiconductor according to an embodiment 5 of the present invention. The same marks as those shown in FIG. 1 according to the embodiment 1, which denote the same components, are not described in detail here. In the construction according to the present embodiment, the memory cell 21 carries a self-diagnosis program for the parts loaded in the test head 11, measurement unit 13, memory 14, power-supply unit/clock generating unit 15 and the like other than the hardware construction for the logic testing function.

Next, it is described about an example of the operation of the test equipment for semiconductor constructed as mentioned above. After the load board C is mounted on the test head 11 of the equipment main body A, the information is transmitted from the memory cell 21 to the FPGA 12 via the cable or the like. The FPGA 12 is configured based on the transmitted information. The hardware construction for the logic testing function of the equipment main body A is regulated by the configuration. At the same time as the configuration or at a different timing, the self-diagnosis program is written in the FPGA 12 from the information. The self-diagnosis program is executed in the FPGA 12 immediately after the program is written or based on the control by the PC/EWS 100 or the like. The self-diagnosis program diagnoses, for example, whether or not the signal outputted from the FPGA 12 is equivalent to the data stored in the memory 14, or whether or not the signal is inputted/outputted at a preset timing. The operation thereafter is the same as described in the embodiment 1.

In the present embodiment, the self-diagnosis program is stored in the memory cell 21, and the self-diagnosis program can be executed in the FPGA 12 at the time when the load-board C is mounted. Thereby, the test can be carried out at a high reliability as the equipment main body A can be always self-diagnosed prior to the test. Therefore, when any abnormality is detected by the self-diagnosis of the equipment main body A, a warning signal is outputted, or a spare part built in preliminarily is used instead of a part showing the abnormality in order that the test can be done at a higher reliability.

### Embodiment 6

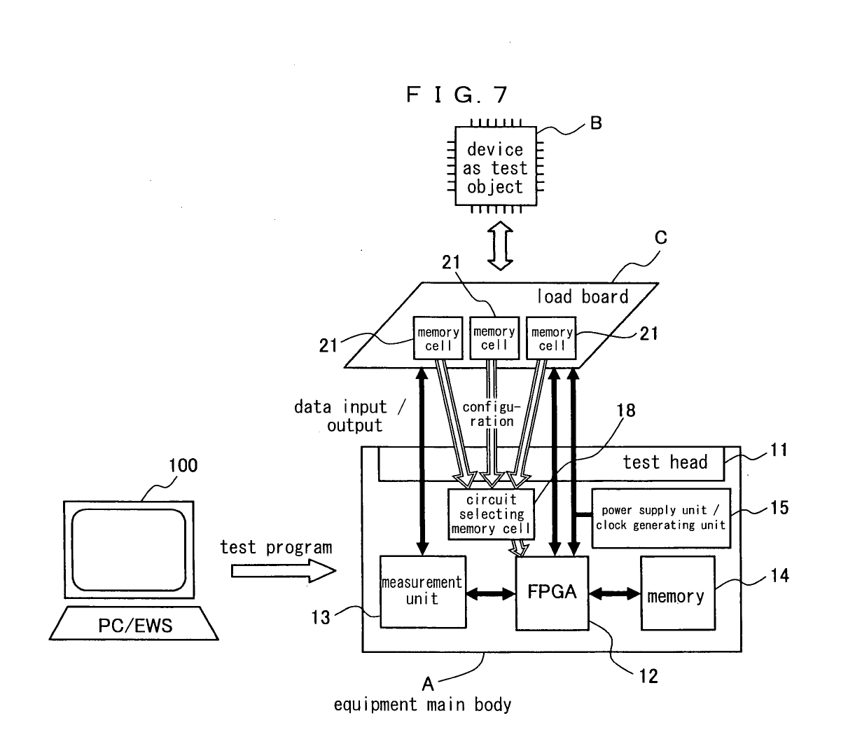

FIG. 7 is a block diagram illustrating a schematic construction of a test equipment for semiconductor according to an embodiment 6 of the present invention. The same marks as those shown in FIG. 1 according to the embodiment 1, which denote the same components, are not described in detail here. In the present embodiment, a plurality of memory cells 21 are mounted on the load board C, and a circuit selecting the memory cell 18 is built in the equipment main body A. Three memory cells are shown in FIG. 7 as the memory cell 21 but the number of the memory cells is not limited to three. The circuit selecting the memory cell 18 corresponds to the plurality of memory cells.

Next, it is described about an example of the operation of the test equipment for semiconductor constructed as mentioned above. When the load board C is mounted on the test head 11 of the equipment main body A, the circuit selecting the memory cell 18 selects one of the memory cells 21 mounted on the load board C. The information is transmitted to the FPGA 12 from the memory cell 21 selected by the circuit selecting the memory cell 18. The FPGA 12 is configured based on the transmitted information. The hardware construction for the logic testing function of the equipment main body A is regulated by the configuration. The operation thereafter is the same as described in the embodiment 1.

In the construction according to the present embodiment, wherein the plurality of memory cells 21 are mounted on the load board C, and the circuit selecting the memory cell 18 is built in the equipment main body A, one of the plurality of memory cells 21 is selected by the circuit selecting the memory cell 18 under the control by the PC/EWS 100 before or after, or during the test. Thereby, a plurality of hardware constructions of the logic testing function can be realized by one load board. For example, if it is necessary for the hardware construction to be different in each of a plurality of tests of a device B as a test object, the memory cells 21 are switched from one to another during the test so that the test can be performed based on the optimum hardware construction in each test without changing the load board C.

### Embodiment 7

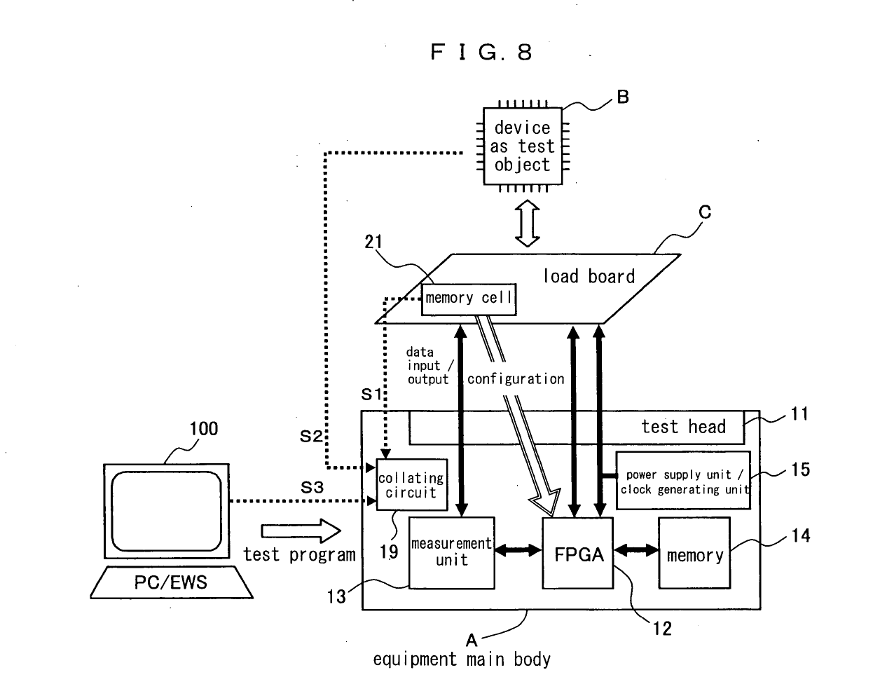

FIG. 8 is a block diagram illustrating a schematic construction of a test equipment for semiconductor according to an embodiment 7 of the present invention. The same marks as those shown in FIG. 1 according to the embodiment 1, which denote the same components, are not described in detail here. In the present embodiment, a collate circuit 19 is built in the equipment main body A. The collate circuit 19 collates one another among a discrimination signal S1 from the memory cell 21, a discrimination signal S2 from the device B to be tested and a discrimination signal S3 from the PC/EWS 100 or the like, and then outputs a signal based on a result of the collation.

Next, description is given about an example of the operation of the test equipment for semiconductor constructed as mentioned above. After the load board C is mounted on the test head 11 of the equipment main body A, the information is transmitted from the memory cell 21 to the FPGA 12 via the cable or the like. The FPGA 12 is configured based on the transmitted information. The hardware construction for the logic testing function of the equipment main body A is regulated by the configuration. At the same time as the configuration or at a different timing, the discrimination signal S1 is transmitted from the memory cell 21 to the collate circuit 19.

After the foregoing preparation, the discrimination signal S3 of the test program and the discrimination signal S2 of the device B as the test object are transmitted to the collate circuit 19 prior to or during the execution of the test program by the PC/EWS 100. The collate circuit 19 collates the discrimination signals S2 and S3 with the discrimination signal S1. The two discrimination signals (S2 and S1) and (S3 and S1) and the three discrimination signals (S2, S3 and S1) are subjected to the collation. The collate circuit 19 judges that the test can be performed when the collation result is correct. The operation thereafter is the same as described in the embodiment 1.

In the present embodiment, it can be confirmed whether or not the appropriate test program (PC/EWS 100), load board and memory cell are used in the test of the device B as the test object, and the warning signal is outputted or the test can be terminated when the collation result is not right. The foregoing construction can eliminate such a risk that the device B as the test object may be tested under improper conditions, and thereby the reliability of the test is much improved.

While there has been described what is at present considered to be preferred embodiments of this invention, it will be understood that various modifications may be given therein to combination and arrangement of the parts, and it is intended to cover all such modifications in the appended claims as fall within the true spirit and scope of this invention.

What is claimed is:

1. A test equipment for semiconductor comprising:
a equipment main body; and
a memory cell provided in an outside of the equipment main body, wherein
the equipment main body comprises a configurable device capable of constructing a hardware construction in a programmable manner and an interface for connecting the configurable device to the outside of the equipment main body in order to configure the configurable device, and
the memory cell, in which a regulation program for a hardware construction to regulate the hardware construction of the configurable device is written, is connected in freely attached or removed way to the equipment main body via the interface.

2. The test equipment for semiconductor as recited in claim 1, wherein
a test program in which an operation of the test equipment for semiconductor is regulated is executed after the configurable device is configured based on the regulation program for the hardware construction read out from the memory cell.

3. The test equipment for semiconductor as recited in claim 1, wherein
the interface comprises a connector or a pogo pin to which a device to be tested by the test equipment for semiconductor is connected.

4. A test equipment for semiconductor as recited in claim 1, further comprising a load board for connecting a device to be tested by the test equipment for semiconductor to the equipment main body, wherein the memory cell is mounted on the load board.

5. A test equipment for semiconductor as recited in claim 1, further comprising a personal computer connected to the test equipment for semiconductor in order to execute a test program by which an operation of the test equipment for semiconductor is regulated, and
the memory cell is loaded in the personal computer.

6. A test equipment for semiconductor as recited in claim 1, further comprising a circuit recognizing memory cell for recognizing a connection state of the memory cell and outputting a result of the recognition.

7. A test equipment for semiconductor as recited in claim 6, further comprising another memory cell built in the equipment main body, in which another regulation program for the hardware construction to regulate another hardware construction of the configurable device is written, wherein
the configurable device reads out the regulation program for the hardware construction of the memory cell to be configured when the circuit recognizing memory cell recognizes the connection of the memory cell, while the configurable device reads out the another regulation program for the hardware construction of the another memory cell to be configured when the circuit recognizing memory cell does not recognize the connection of the memory cell.

8. A test equipment for semiconductor as recited in claim 6, further comprising a personal computer and another memory cell, wherein
the personal computer is connected to the test equipment for semiconductor and executes a test program in which an operation of the test equipment for semiconductor is regulated,
the another memory cell is loaded in the personal computer, wherein another regulation program for the hardware construction for regulating another hardware construction of the configurable device is written in the another memory cell, and
the configurable device reads out the regulation program for the hardware construction of the memory cell to be configured when the circuit recognizing memory cell recognizes the connection of the memory cell, while the configurable device reads out the another regulation program for the hardware construction of the another memory cell to be configured when the circuit recognizing memory cell does not recognize the connection of the memory cell.

9. A test equipment for semiconductor as recited in claim 4, wherein
a board characteristic information of the load board is memorized in the memory cell, and
the configurable device performs a test program in which an operation of the test equipment for semiconductor is regulated based on the board characteristic information of the load board read out from the memory cell.

10. A test equipment for semiconductor as recited in claim 1, wherein a self-diagnosis program for automatically diagnosing parts loaded in the equipment main body is written in the memory cell, and
the test equipment for semiconductor executes the self-diagnosis program read out from the memory cell as a preliminary process of a test based on a test program in which an operation of the test equipment for semiconductor is regulated.

11. A test equipment for semiconductor as recited in claim 1, further comprising a circuit selecting the memory cell and a plurality of memory cells, wherein
the circuit selecting the memory cell selects an arbitrary memory cell from the plurality of memory cells connected to the interface, and
a test is performed based on a test program in which an operation of the test equipment for semiconductor is regulated after the configurable device is configured based on the regulation program for the hardware construction read out from the memory cell selected by the circuit selecting the memory cell.

12. A test equipment for semiconductor as recited in claim 1, further comprising a collate circuit for collating a discrimination signal of the regulation program for the hardware construction written in the memory cell with a discrimination signal of a device to be tested by the test equipment for semiconductor to output a result of the collation, and
the configurable device executes a test program in which an operation of the test equipment for semiconductor is regulated based on the collation result by the collate circuit.

13. A test equipment for semiconductor as recited in claim 1, further comprising:
a personal computer connected to the test equipment for semiconductor in order to execute a test program in which an operation of the test equipment for semiconductor is regulated; and
a collate circuit for collating a discrimination signal of the regulation program for the hardware construction written in the memory cell with a discrimination signal of the personal computer to output a result of the collation, wherein
the configurable device executes a test program in which an operation of the test equipment for semiconductor is regulated based on the collation result of the collate circuit.
